(19) United States
(12) Patent Application Publication
(10) Pub. No.: US 2010/0102351 A1
(43) Pub. Date: Apr. 29, 2010

(54) Semiconductor Light Emitting Device and Method of Manufacturing the Same

(75) Inventors: Chang Tae Kim, Seongnam-si (KR); Tae Hee Lee, Yesan-gun (KR); Hyun Min Jung, Seongnam-si (KR); Gi Yeon Nam, Seongnam-si (KR)

Correspondence Address: HARNESS, DICKEY, & PIERCE, P.L.C, 7700 Bonhomme, Suite 400, ST. LOUIS, MO, 63105, US

(73) Assignee: EPIVALLEY CO., LTD., Gumi-city (KR)

(21) Appl. No.: 12/646,150

(22) Filed: Dec. 23, 2009

Related U.S. Application Data
(63) Continuation of application No. PCT/KR2008/003756, filed on Jun. 27, 2008.

(30) Foreign Application Priority Data
Jun. 27, 2007 (KR) 10-2007-0063665
Aug. 23, 2007 (KR) 10-2007-0084776

(51) Int. Cl. H01L 33/00; H01L 21/302

(52) U.S. Cl. 257/98; 438/29; 257/E33.074; 257/E21.214

(57) ABSTRACT

The present disclosure relates to a semiconductor light-emitting device and a method of manufacturing the same, and more particularly, to a III-nitride semiconductor light-emitting device which improves external quantum efficiency by forming an irregular portion on a surface of a semiconductor layer by a protrusion formed on a substrate, and a method of manufacturing the same.

### CROSS-REFERENCE TO RELATED APPLICATIONS

This application is a continuation of PCT Application No. PCT/KR2008/003756 filed on Jun. 27, 2008, which claims the benefit and priority to Korean Patent Application Nos. 10-2007-0063665, filed Jun. 27, 2007 and 10-2007-0084776, filed Aug. 23, 2007. The entire disclosures of the applications identified in this paragraph are incorporated herein by reference.

### FIELD

The present disclosure relates to a semiconductor light-emitting device and a method of manufacturing the same, and more particularly, to a III-nitride semiconductor light-emitting device which improves external quantum efficiency by forming an irregular portion on a surface of a semiconductor layer by a protrusion formed on a substrate, and a method of manufacturing the same. Herein, a III-nitride semiconductor refers to a GaN-based semiconductor, but may further include another semiconductor, such as SiCN.

### BACKGROUND

This section provides background information related to the present disclosure which is not necessarily prior art.

FIG. 1 is a view illustrating one example of a semiconductor light-emitting device described in U.S. Pat. No. 5,429,954. Irregular portions 10 are formed on surfaces of a semiconductor light-emitting device 1. The irregular portions 10 serve to increase an external extraction amount of light generated from an active layer 6.

FIG. 2 is a view illustrating one example of a III-nitride semiconductor light-emitting device described in U.S. Pat. No. 6,809,340, particularly, an n-type nitride semiconductor layer 103, a p-type nitride semiconductor layer 106, a p-side electrode 107, and an n-side electrode 108. Irregular portions 109 are formed on surfaces of the p-type nitride semiconductor layer 106. The irregular portions 109 can be formed by etching and masking.

### SUMMARY

This section provides a general summary of the disclosure, and is not a comprehensive disclosure of its full scope or all of its features.

There is provided a semiconductor light-emitting device which can improve external quantum efficiency, and a method of manufacturing the same.

There is also provided a semiconductor light-emitting device which improves external quantum efficiency by eliminating debris left on the device during a chipping process during manufacture of the device, and a method of manufacturing the same.

In another embodiment, there is provided a semiconductor light-emitting device which improves external quantum efficiency by using a scattering surface formed on the surface of a semiconductor layer by a pattern or protrusion provided on a substrate, and a method of manufacturing the same.

In yet another embodiment, there is provided a III-nitride semiconductor light-emitting device which improves external quantum efficiency by forming an irregular portion on a surface of a semiconductor layer by a pattern or protrusion formed on a substrate, and a method of manufacturing the same.

In a particular embodiment, a substrate is formed of a sapphire, and a plurality of semiconductor layers are formed of a III-nitride semiconductor. An active layer is mostly formed of InGaN. A buffer layer can be applied to the lowest layer of the plurality of semiconductor layers in order to reduce mismatching with a substrate. The buffer layer can be formed of AlGaN, AlN, SiC, etc.

An irregular portion of the substrate can be formed by forming protrusion and/or depression portions on the substrate, and an etching can be a dry etching and/or wet etching. A method of forming a pattern on a substrate has been well-known to those skilled in this field. After a target pattern is formed, a protrusion can be formed by means of an ICP/RIE. In some particular embodiments, the protrusion has an elliptical or circular shape so as to stably form a scattering surface.

Exposure or scribing can be carried out by means of a laser and/or diamond cutter. The laser is advantageous because of its process speed. However, debris is generated on the device after the scribing using the laser, which has a detrimental effect on external quantum efficiency of the device.

According to a semiconductor light-emitting device and a method of manufacturing the same of the present disclosure, the external quantum efficiency of the light-emitting device can be improved.

Also, according to a semiconductor light-emitting device and a method of manufacturing the same of the present disclosure, the external quantum efficiency of the light-emitting device can be improved by eliminating debris left on the device during a chipping process during manufacture of the device.

Also, according to a semiconductor light-emitting device and a method of manufacturing the same of the present disclosure, the external quantum efficiency can be improved by a scattering surface formed on the surface of a semiconductor layer by a pattern or protrusion provided on a substrate.

Also, according to the a III-nitride semiconductor light-emitting device and a method of manufacturing the same of the present disclosure, the external quantum efficiency can be improved by forming an irregular portion on a surface of a semiconductor layer by a pattern or protrusion formed on a substrate.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a view illustrating one example of a semiconductor light-emitting device described in U.S. Pat. No. 5,429,954.

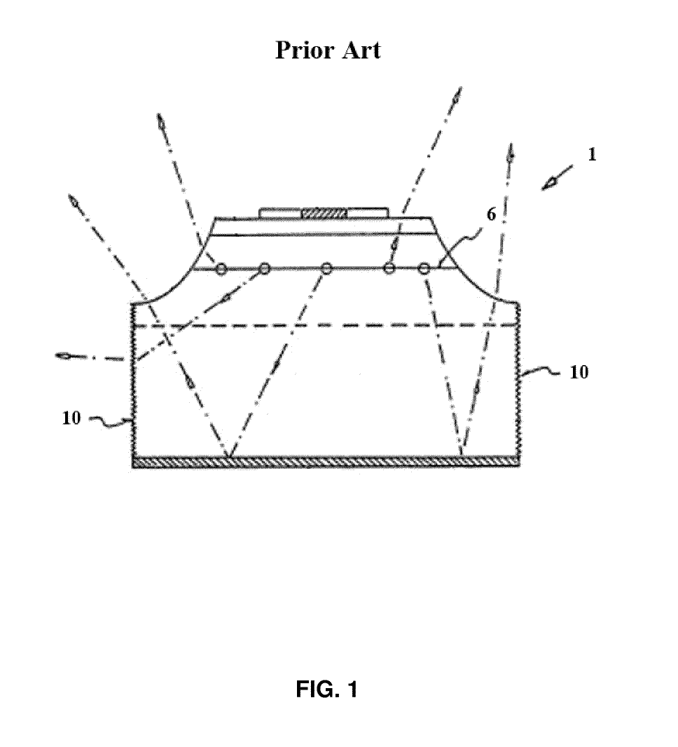

FIG. 2 is a view illustrating one example of a III-nitride semiconductor light-emitting device described in U.S. Pat. No. 6,809,340.

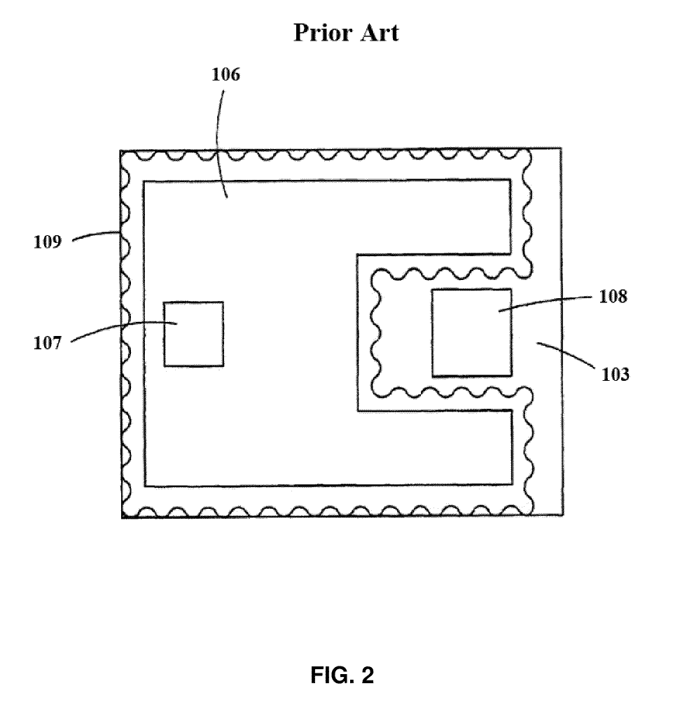

FIG. 3 is a view illustrating a semiconductor light-emitting device according to an embodiment of the present disclosure.

FIG. 4 is an enlarged view illustrating an interface between a plurality of semiconductor layers and a substrate in a semiconductor light-emitting device according to the present disclosure.

FIG. 5 is a photograph showing a semiconductor light-emitting device according to an embodiment of the present disclosure.

FIG. 6 is a photograph showing a section of a semiconductor light-emitting device according to an embodiment of the present disclosure.

FIG. 7 is a photograph showing an entire scattering surface according to the present disclosure.

FIG. 8 is a photograph taken before an etching.

FIG. 9 is a photograph showing a semiconductor light-emitting device according to another embodiment of the present disclosure.

Corresponding reference numerals indicate corresponding parts throughout the several views of the drawings.

### DETAILED DESCRIPTION

Hereinafter, the present disclosure will be described in detail with reference to the accompanying drawings.

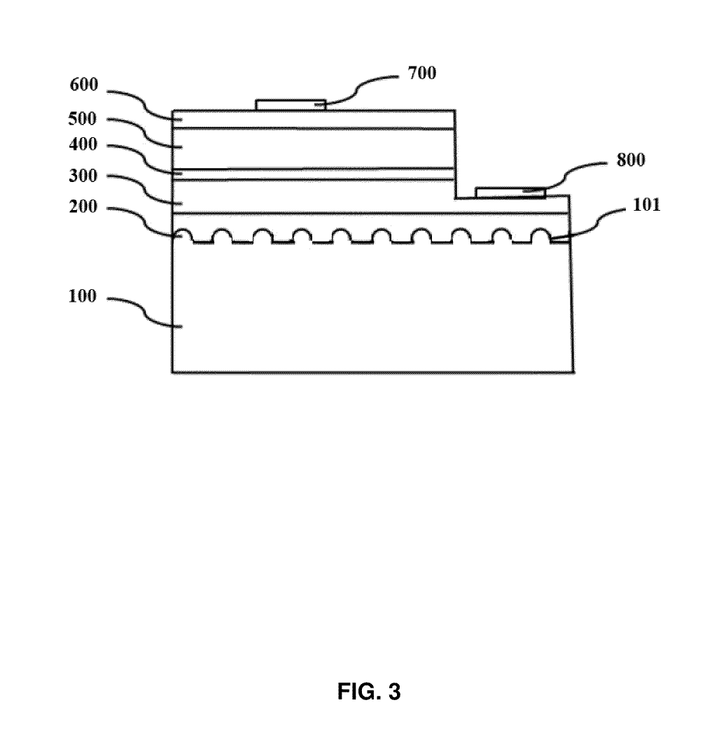

FIG. 3 is a view illustrating a semiconductor light-emitting device according to an embodiment of the present disclosure. The semiconductor light-emitting device includes a sapphire substrate 100, a buffer layer 200 epitaxially grown on the sapphire substrate 100, an n-type nitride semiconductor layer 300 epitaxially grown on the buffer layer 200, an active layer 400 epitaxially grown on the n-type nitride semiconductor layer 300, a p-type nitride semiconductor layer 500 epitaxially grown on the active layer 400, a transparent electrode layer 600 formed on the p-type nitride semiconductor layer 500, a p-side contact metal layer 700 formed on the transparent electrode layer 600, and an n-side contact metal layer 800 formed on the n-type nitride semiconductor layer exposed by mesa-etching the p-type nitride semiconductor layer 500, and the active layer 400. Circular protrusions 101 for forming a scattering surface on the surface of the nitride semiconductor layers are formed on the sapphire substrate 100.

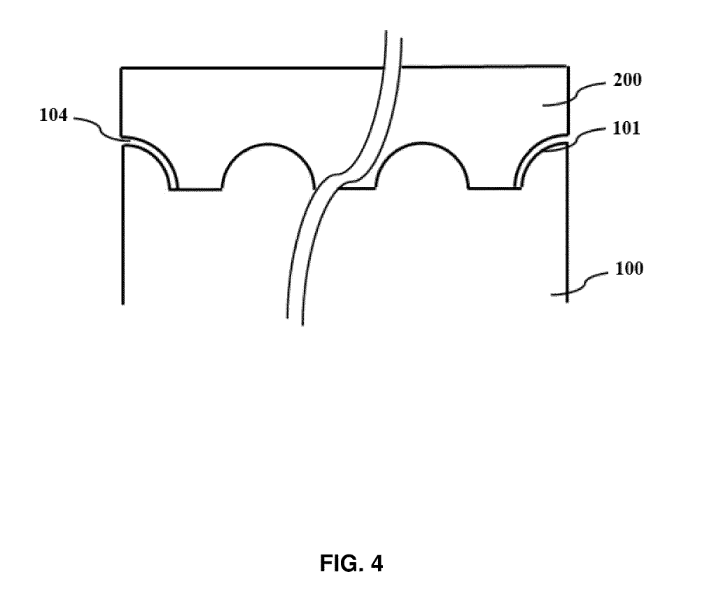

FIG. 4 is an enlarged view illustrating an interface between a plurality of semiconductor layers and a substrate in a semiconductor light-emitting device according to the present disclosure. A scattering surface 104 is spaced apart from protrusions 101 of a sapphire substrate 100 to scatter light and is formed to be upwardly convex. In accordance with the present disclosure, the scattering surface 104 serves to improve external quantum efficiency of the semiconductor light-emitting device.

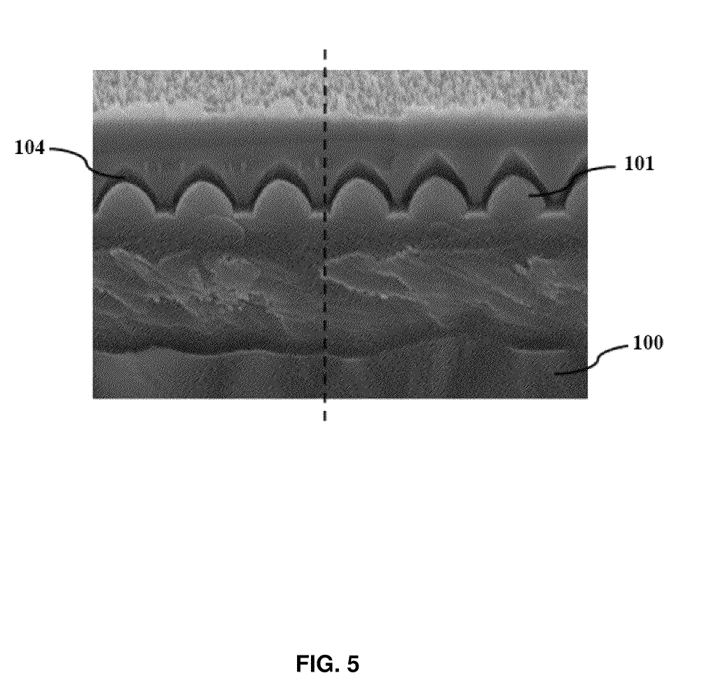

FIG. 5 is a photograph showing a semiconductor light-emitting device according to an embodiment of the present disclosure. Protrusions 101 are formed on a sapphire substrate 100, and a scattering surface 104 is formed at an interval from the protrusions 101.

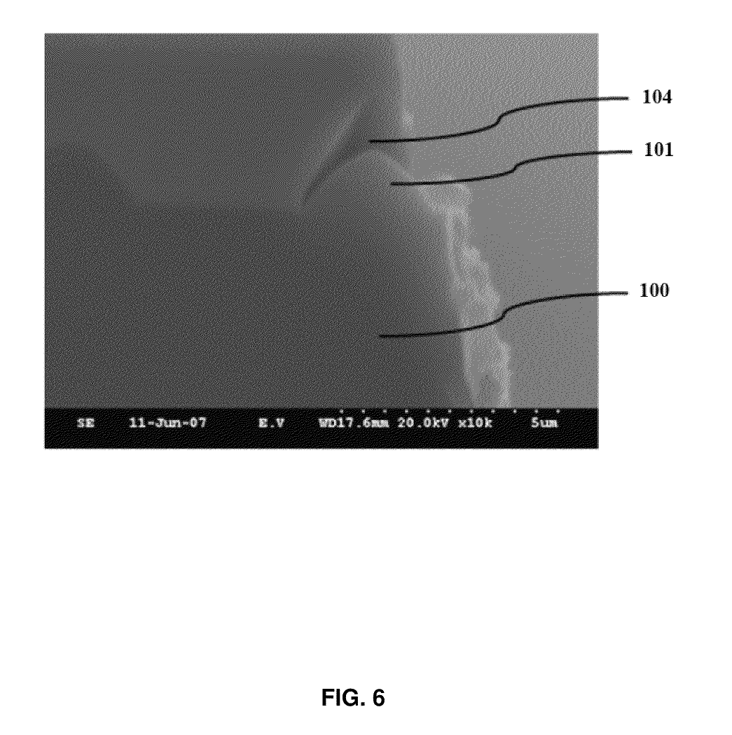

FIG. 6 is a photograph showing a section of a semiconductor light-emitting device according to an embodiment of the present disclosure. Protrusions 101 are formed on a sapphire substrate 100, and a scattering surface 104 is formed along the shape of the protrusions 101. An interval between the protrusion 101 and the scattering surface 104 is reduced in an inward direction of the device.

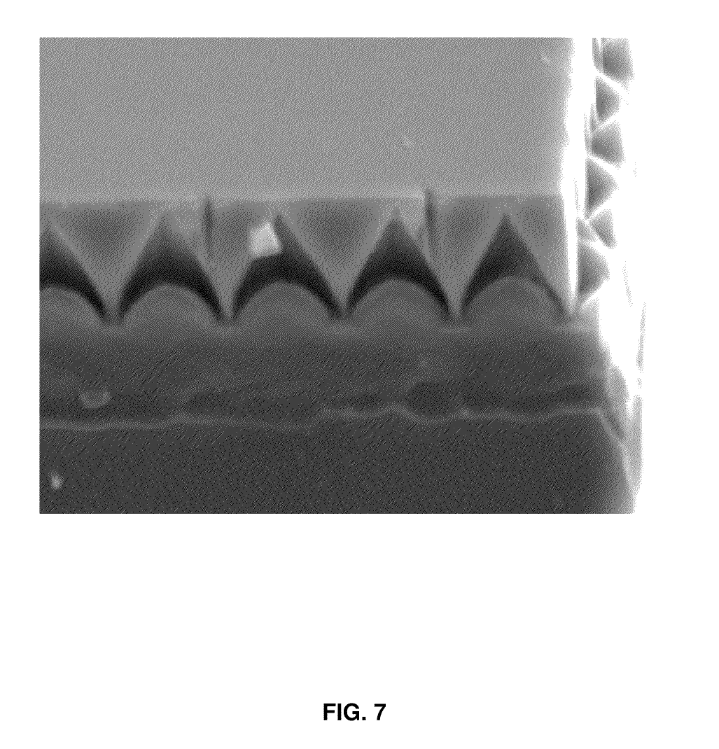

FIG. 7 is a photograph showing an entire scattering surface according to the present disclosure. The scattering surface is much larger than the entire surface of protrusion. The scattering surface is formed between the outside; i.e., the air and semiconductor layers.

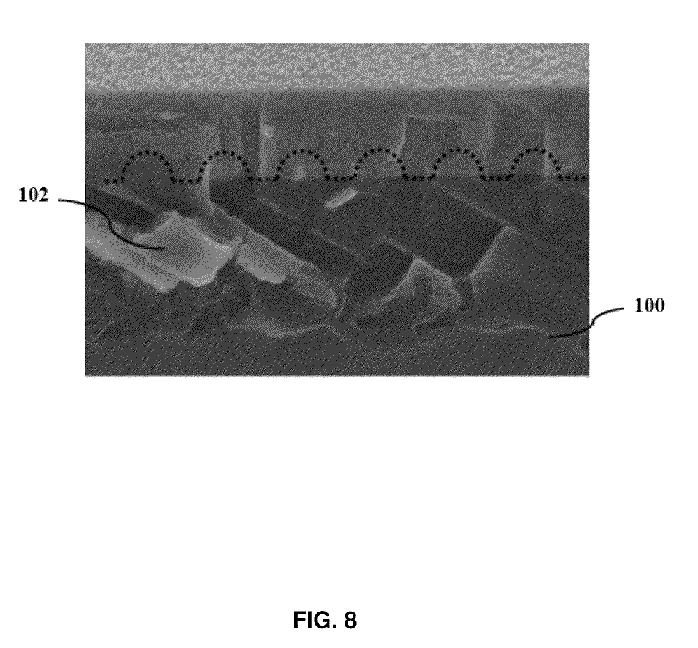

FIG. 8 is a photograph taken before an etching. Protrusions of a sapphire substrate 100 are supposed to be shown in dotted line parts, but are hidden by debris 102.

Formation of Scattering Surface

A step of cutting an III-nitride semiconductor light-emitting device into individual devices (chipping step) can be carried out by means of a laser. In some embodiments, a depth and width of a cutting surface of a substrate range from 0.5 μm to 30 μm (e.g., 15 μm) so that the individual light-emitting devices can be easily separated by a physical force. If the depth of the cutting surface is below 0.5 μm, in the process of thinly cutting the surface of a light-emitting device and physically separating each light-emitting device, such as in a cutting method using a diamond tip, the surface and the inside of the light-emitting device may become cracked, or an electrical characteristic thereof may be degraded. On the other hand, if the depth of the cutting surface is over 30 μm, then the light-emitting device may easily break during manufacture, resulting in low productivity.

A step of attaching a protective film can be further included prior to a step of etching the side of the III-nitride semiconductor light-emitting device. The protective film can be formed of any one of etching-resistant materials such as silicon oxide, photoresist and silicon, or any combination thereof.

HCl, HNO₃, HF, H₂SO₄, H₃PO₄ and so on can be used in the step of etching the surface of the III-nitride semiconductor light-emitting device. In some embodiments, the roughness of the etched surface is below a few tens of nanometers. If the roughness of the etched side is over a few tens of nanometers, the etched surface functions, like debris, to lower light extraction efficiency of the light-emitting device. In some embodiments, an etching fluid is used when it is heated over 150° C. If a temperature of the etching fluid is below 150° C., a etching ratio of the surface decreases. Accordingly, there is a limitation on changing the shape of the device to easily extract light in the present disclosure. In the meantime, BCL₃, Cl₂, HBr, Ar and so on can be used as etching gases for dry etching. Without being bound by theory, it is thought that an interface between the sapphire substrate and the semiconductor is actively etched because the boundary is an unstable interface generated by the epitaxial growth between different materials. A buffered oxide etchant (BOE) can also be used as an etching fluid.

For example, the light-emitting device can be processed/dried by ultrasonic waves for 10 minutes, and etched by H₃PO₄ for 10 minutes at an etching temperature of about 200° C. (the etching temperature starts from 210° C. and maintains at 200° C.).

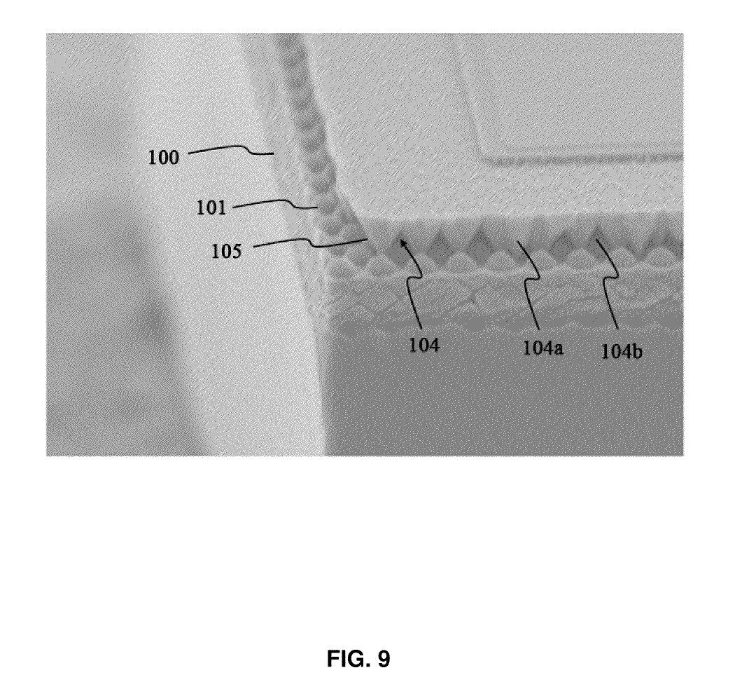

FIG. 9 is a photograph showing a semiconductor light-emitting device according to another embodiment. Protrusions 101 are formed on a sapphire substrate 100, and a scattering surface 104 is formed at an interval from the protrusions 101. Different from the side shown in FIG. 7, this side has an inclined face 105 because of a further etching (e.g., wet etching at 200 to 300° C. for 5 to 10 min.). The scattering surface 104 is so etched to reach a top surface of a p-type nitride semiconductor layer 500, thereby forming an irregular portion 104a and 104b (the scattering surface 104 defines the depression portions 104b). As a result, more light can be externally extracted by the inclined face 105 as well as the irregular portion 104a and 104b. Therefore, the irregular portion 104a and 104b and/or the inclined face 105 can be formed in an epitaxial growth direction by controlling an etching time without using a special pattern.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

1. A semiconductor light-emitting device, comprising:
a substrate with a protrusion formed thereon;
a plurality of semiconductor layers formed over the substrate, and including an active layer for generating light by recombination of electrons and holes; and a scattering surface spaced apart from the protrusion on an interface between the substrate and the plurality of semiconductor layers to improve external extraction of light generated in the active layer.

2. The semiconductor light-emitting device of claim 1, wherein the scattering surface is upwardly convex toward the active layer.

3. The semiconductor light-emitting device of claim 1, wherein an interval between the scattering surface and the substrate decreases toward the inside of the plurality of semiconductor layers.

4. The semiconductor light-emitting device of claim 2, wherein an interval between the scattering surface and the substrate decreases toward the inside of the plurality of semiconductor layers.

5. The semiconductor light-emitting device of claim 1, wherein the substrate is a sapphire substrate.

6. The semiconductor light-emitting device of claim 4, wherein the substrate is a sapphire substrate.

7. The semiconductor light-emitting device of claim 1, wherein the active layer is formed of a III-nitride semiconductor.

8-13. (canceled)

14. A method of manufacturing a semiconductor light-emitting device, comprising:
(a) growing a plurality of nitride semiconductor layers over a substrate;
(b) scribing the plurality of nitride semiconductor layers; and
(c) forming a scattering surface by etching an interface between the substrate and the plurality of nitride semiconductor layers through a scribed surface.

15. The method of claim 14, further comprising forming a protrusion on the substrate prior to step (a).

16. The method of claim 15, wherein the scattering surface is formed by etching an interface between the protrusion of the substrate and the plurality of nitride semiconductor layers.

17. The method of claim 16, wherein step (b) is performed using a laser, and the step (c) is performed by wet etching.

18. The method of claim 17, wherein the substrate is a sapphire substrate.

19. The method of claim 17, wherein debris left on the scribed surface in the scribing using a laser of step (b) is eliminated by the wet etching of step (c).

20. The method of claim 15, wherein the scattering surface is upwardly convex toward an active layer.

21. A semiconductor light-emitting device, comprising:
a substrate with a protrusion formed thereon;
a plurality of semiconductor layers formed over the substrate, and including an active layer for generating light by recombination of electrons and holes; and
an irregular portion formed on a surface of the plurality of semiconductor layers in a stacked direction of the plurality of semiconductor layers to scatter light generated in the active layer, a depression portion of which being defined by removing the plurality of semiconductor layers on the protrusion.

22. The semiconductor light-emitting device of claim 21, wherein at least a part of the sides of the plurality of semiconductor layers forms an inclined face.

23. The semiconductor light-emitting device of claim 21, wherein the substrate is a sapphire substrate.

24-25. (canceled)

26. A method of manufacturing a semiconductor light-emitting device, comprising:
(a) forming an irregular portion on a substrate;
(b) growing a plurality of semiconductor layers over the substrate; and
(c) forming an irregular portion in a stacked direction of the plurality of semiconductor layers to scatter light generated in an active layer, by etching a surface of the plurality of semiconductor layers and an interface between the substrate and the plurality of semiconductor layers.

27. The method of claim 26, wherein the irregular portion of step (c) is shaped by the irregular portion of the substrate.

28. The method of claim 27, wherein the irregular portion is formed to reach an upper portion of the plurality of semiconductor layers.

29. The method of claim 27, further comprising exposing the surface of the plurality of semiconductor layers and the interface between the substrate and the plurality of semiconductor layers, before step (c).

30-32. (canceled)

33. A semiconductor light-emitting device, comprising:
a substrate;
a plurality of semiconductor layers formed over the substrate, and including an active layer for generating light by recombination of electrons and holes; and
an irregular portion formed on a surface of the plurality of semiconductor layers in a stacked direction of the plurality of semiconductor layers to scatter light generated over the active layer, a width of a protrusion portion of which being increased in the stacked direction of the plurality of semiconductor layers.

34. The semiconductor light-emitting device of claim 33, wherein the substrate comprises a protrusion, and a depression portion of the irregular portion is defined on the protrusion.

35. The semiconductor light-emitting device of claim 34, wherein the active layer is formed of a nitride semiconductor.

36. A semiconductor light-emitting device, comprising:
a substrate with an irregular portion formed thereon, at least a part of the irregular portion being exposed; and
a plurality of semiconductor layers formed over the substrate to cover the non-exposed irregular portion, including an active layer for generating light by recombination of electrons and holes, and having an inclined side.

37. The semiconductor light-emitting device of claim 36, wherein the irregular portion is formed on the inclined side.

38. The semiconductor light-emitting device of claim 36, wherein the substrate is a sapphire substrate.
